(19) United States
(12) Patent Application Publication
(10) Pub. No.: US 2025/0022765 A1
(43) Pub. Date: Jan. 16, 2025

(54) TOP SIDE COOLING FOR POWER AMPLIFIER MODULE

(71) Applicant: Qorvo US, Inc., Greensboro, NC (US)

(72) Inventors: Miles Larkin, Dallas, TX (US); MD Hasnine, Richardson, TX (US); Neftali Salazar, Oak Ridge, NC (US); Charles E. Carpenter, Orlando, FL (US); Thomas Scott Morris, Lewisville, NC (US); Mark C. Woods, Richardson, TX (US); Thomas Landon, JR., Plano, TX (US); Anthony Chiu, Richardson, TX (US)

(21) Appl. No.: 18/734,290

(22) Filed: Jun. 5, 2024

Related U.S. Application Data
(60) Provisional application No. 63/534,594, filed on Aug. 25, 2023.
(60) Provisional application No. 63/526,344, filed on Jul. 12, 2023.

(51) Int. Cl. H01L 23/367; H01L 23/00; H01L 23/498; H03F 3/24

(52) U.S. Cl. CPC H01L 23/367; H01L 23/49822; H01L 23/49827; H01L 24/48; H01L 2224/48225; H03F 3/245

(57) ABSTRACT

Systems and methods for top side cooling for a power amplifier module are disclosed. The power amplifier module may be part of a system in a package that may be considered inverted relative to a normal orientation. A power amplifier die (and other elements) may be mounted on a metallization layer. Wire bond connections may communicatively couple the “top” of the power amplifier die to the metallization layer. A plated heat sink (PHS) laminate may be positioned “beneath” the power amplifier die in the metallization layer. The metallization layer may communicatively couple to vias that extend “up” and “above” the power amplifier die to a connection pad. The entire package is then inverted such that the connection pads may couple to a printed circuit board in a downward direction, and the PHS is now facing upward so that it may be coupled to a heat sink.

### PRIORITY APPLICATIONS

This application claims the benefit of U.S. Provisional Patent Application Ser. No. 63/534,594, filed on Aug. 25, 2023, the disclosure of which is hereby incorporated herein by reference in its entirety.

This application claims the benefit of U.S. Provisional Patent Application Ser. No. 63/526,344, filed on Jul. 12, 2023, the disclosure of which is hereby incorporated herein by reference in its entirety.

### BACKGROUND

### I. Field of the Disclosure

The technology of the disclosure relates generally to cooling a power amplifier module using top side cooling.

### II. BACKGROUND

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been an evolution in the wireless protocols used to convey information to and from the mobile communication devices. The new protocols have placed new demands on transceivers and particularly power amplifiers used by transceivers to send wireless signals. These increased demands mean that many of the power amplifiers are generating waste heat. Removing this waste heat before it damages components in the mobile communication device provides room for innovation.

### SUMMARY

Aspects disclosed in the detailed description include systems and methods for top side cooling for a power amplifier module. In particular, the power amplifier module may be part of a system in a package that may be considered inverted relative to a normal orientation. In this regard, before inversion, a power amplifier die (and other elements) may be mounted on a metallization layer. Wire bond connections may communicatively couple the “top” of the power amplifier die to the metallization layer. A plated heat sink (PHS) laminate may be positioned “beneath” the power amplifier die in the metallization layer. The metallization layer may communicatively couple to vias that extend “up” and “above” the power amplifier die to a connection pad. The entire package is then inverted such that the connection pads may couple to a printed circuit board or other substrate in a downward direction, and the PHS is now facing upward so that it may be coupled to a heat sink or fan element. Thus, the signal paths now go “down,” and the heat dissipation paths now go “up.” By separating the signal paths from the heat dissipation paths, performance is improved. Additionally, heat-related failures are reduced, resulting in a longer device lifetime.

In an exemplary aspect, a package is disclosed. The package includes a metallization layer comprising a PHS configured to be coupled to an external heat sink through a first surface and a plurality of interior metal layers electrically isolated from the PHS. The metallization layer further comprising a plurality of vias coupling different ones of the plurality of interior metal layers and a die positioned adjacent to the PHS at a second surface opposite the first surface, the die coupled to at least one of the interior metal layers through a wire bond connection. The package further includes an external via configured to couple the metallization layer to an exterior surface opposite the first surface.

In another exemplary aspect, a method of routing signals to a die in a package is disclosed. The method includes generating a signal in a die mounted on a plated heat sink (PHS), passing the signal through a wire bond from the die to an interior metal layer within a metallization layer, and passing the signal from the interior metal layer to an external via that routes the signal to an exterior surface opposite the PHS.

In another exemplary aspect, a device is disclosed. The device includes a transceiver comprising a package comprising a metallization layer. The metallization layer includes a PHS configured to be coupled to an external heat sink through a first surface, a plurality of interior metal layers electrically isolated from the PHS, and a plurality of vias coupling different ones of the plurality of interior metal layers. The device further includes a die positioned adjacent to the PHS at a second surface opposite the first surface, the die coupled to at least one of the interior metal layers through a wire bond connection and an external via configured to couple the metallization layer to an exterior surface opposite the first surface.

### BRIEF DESCRIPTION OF THE DRAWINGS

FIG. 1A is a top-down view of an exemplary system in a package having a power amplifier module therein according to aspects of the present disclosure;

FIG. 1B is a side cross-sectional view of FIG. 1A taken along lines 1B-1B with an overmold material applied;

FIG. 2A is a perspective view of a plurality of E-bar interposers that may be used to facilitate signal paths in a package according to exemplary aspects of the present disclosure;

FIG. 2B is a side elevation cross-sectional view of a via in the E-bar interposer of FIG. 2A;

FIG. 3 is a flowchart illustrating an exemplary process for making a package according to exemplary aspects of the present disclosure;

FIG. 4 is a top-down view of a plurality of packages ready to be singulated;

FIG. 5 is a side elevational view of a package using a first mold process;

FIG. 6 is a side elevational view of a package using a second mold process;

FIG. 7 is a side elevational view of a package using a third mold process;

FIG. 8 is a side elevational view of a package using a fourth mold process;

FIG. 9 is a side elevational view of a package using a fifth mold process; and

FIG. 10 is a block diagram of a mobile terminal, which may include the packages illustrated in FIGS. 1A-2B and 4-9 according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element, or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” both broadly to refer to a plurality of circuits that send and receive signals or narrowly to refer to a specific conversion circuit within the plurality of circuits. In the broad sense, the transceiver may include a baseband processor, an up/down conversion circuit, filters, amplifiers, couplers, and the like coupled to one or more antennas. Alternatively, for the narrow sense, some authors in the industry literature use “transceiver” to refer to a single circuit positioned between a baseband processor and a power amplifier circuit. This intermediate circuit may include the up/down conversion circuits, mixers, oscillators, filters, and the like, but generally does not include the power amplifiers. As used herein, the term transceiver is used in the first sense. Where relevant to distinguish between the two definitions, the terms “transceiver chain” and “transceiver circuit” are used respectively.

Further, the term approximately, as used herein, means within five percent (5%).

Aspects disclosed in the detailed description include systems and methods for top side cooling for a power amplifier module. In particular, the power amplifier module may be part of a system in a package that may be considered inverted relative to a normal orientation. In this regard, before inversion, a power amplifier die (and other elements) may be mounted on a metallization layer. Wire bond connections may communicatively couple the “top” of the power amplifier die to the metallization layer. A plated heat sink (PHS) laminate may be positioned “beneath” the power amplifier die in the metallization layer. The metallization layer may communicatively couple to vias that extend “up” and “above” the power amplifier die to a connection pad. The entire package is then inverted such that the connection pads may couple to a printed circuit board or other substrate in a downward direction and the PHS is now facing upward so that it may be coupled to a heat sink or fan element. Thus, the signal paths now go “down,” and the heat dissipation paths now go “up.” By separating the signal paths from the heat dissipation paths, performance is improved. Additionally, heat-related failures are reduced, resulting in a longer device lifetime.

Before addressing exemplary aspects of the present disclosure, an overview of a conventional approach is provided to assist in seeing the benefits of the present disclosure. In this regard, a conventional transceiver may include a power amplifier module or die that generates waste heat during signal amplification. This waste heat may, if unchecked, damage components in the power amplifier module (e.g., remelting solder, melting plastic mold material, or the like). Recognizing this risk, designers have tried to create a thermal path through which the waste heat may dissipate. Since the power amplifier module is attached to a material such as a printed circuit board (PCB), the common approach is to route the waste heat through the PCB. The PCB also serves as a structure through which signaling conductors pass. The juxtaposition of the signaling conductors and the thermal path imposes contradictory design constraints on the designers, adding to the complexity and sometimes resulting in a compromise in performance. One such compromise is that materials such as a PCB are generally poor thermal paths, resulting in less efficient heat transfer.

Exemplary aspects of the present disclosure provide for a bifurcated routing of the waste heat path and the signaling conductors. Specifically, heat may be transferred through the top of a package containing a heat-generating element, such as a power amplifier. Signaling conductors are routed from the die, through a metallization layer, and down through a mold compound to signaling paths in the PCB. Conversely, signals from the PCB pass through vias in the mold compound up to the metallization layer, and then to the die.

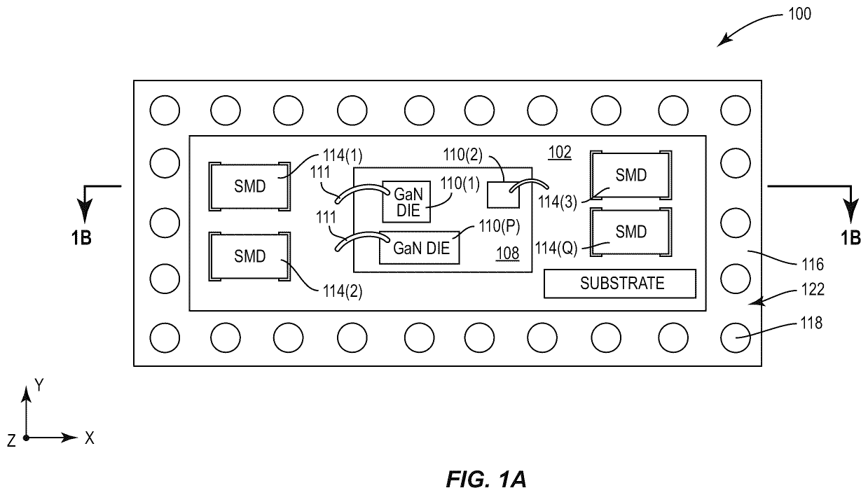

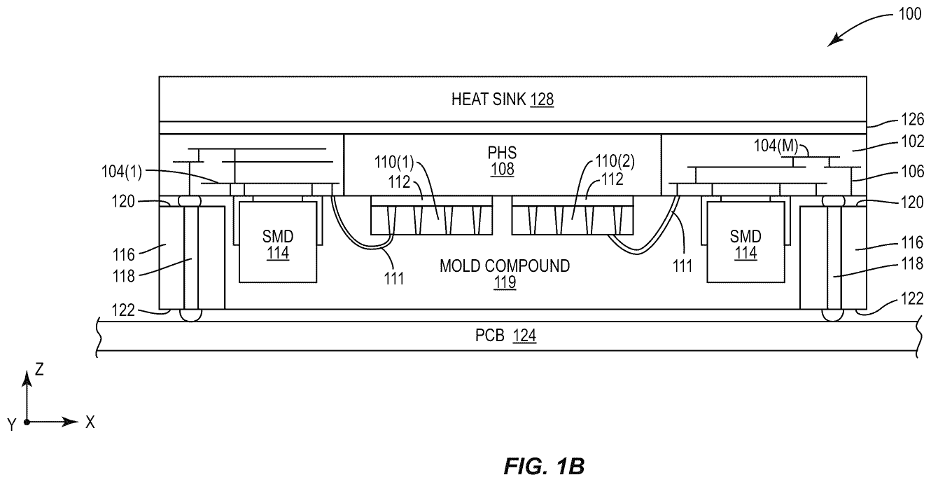

In this regard, FIG. 1A top-down view of a package 100 before mold is applied thereto. FIG. 1B is the same package 100 taken along line 1B-1B of FIG. 1A. More specifically, the package 100 begins with a metallization layer 102, which may sometimes be referred to as a substrate or a laminate. In an exemplary aspect, the metallization layer 102 will include one or more metal layers 104(1)-104(M) (see FIG. 1B) therewithin connected with internal vias 106 that provide interconnections in the z-axis while the metal layers 104(1)-104(M) provide connections in the x-y plane. Relevantly, the metal layers 104(1)-104(M) are within the metallization layer 102 and do not lie on either exterior surface aside from contact points that couple to vias 106 that couple to the top metal layer. The metallization layer 102 may also have a plated heat sink (PHS) 108 therewithin. The PHS 108 may be made from a good thermal conductor such as copper and may be electrically isolated from electrical conductors (e.g., metal layers 104(1)-104(M) and vias 106) in the metallization layer 102. Heat-producing dies 110(1)-110(P) are positioned on top (i.e., in the z-axis) of the PHS 108 and secured thereto with, for example, a high thermal sintered material 112. A plurality of dies may also be referred to herein as “dice.” Additionally, the dice 110(1)-110(P) may be coupled to metal layers 104(1)-104(M) by wire bond connections 111. In an exemplary aspect, the dice 110(1)-110(P) may be power amplifier dice including, for example, gallium nitride (GaN) power amplifiers. Additional elements such as surface-mounted devices (SMD) 114(1)-114(Q) (generically 114) may also be mounted on the metallization layer 102 and connected to metal layers 104(1)-104(M) as is well understood.

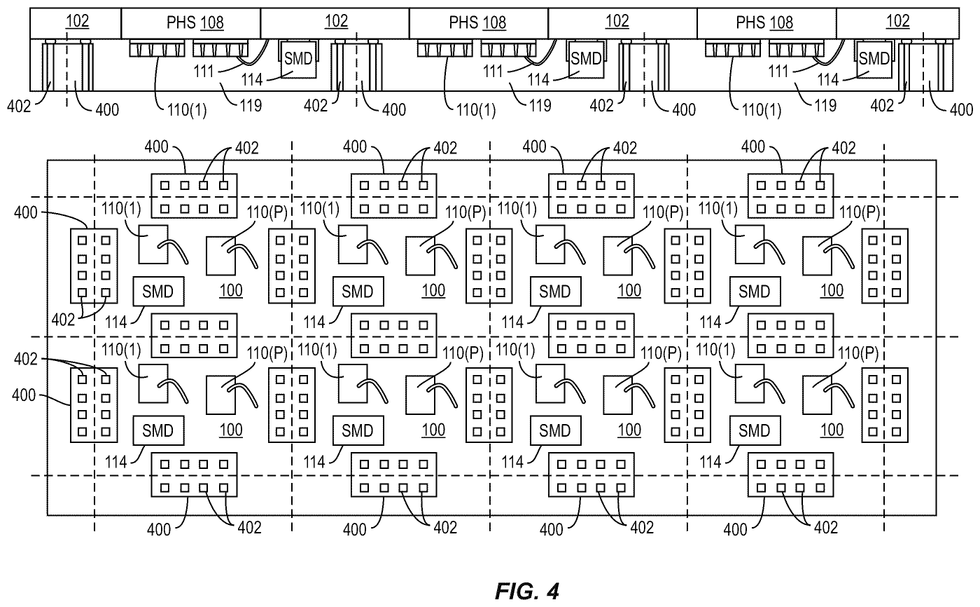

The package 100 may further include an e-bar interposer 116. In a first aspect, the e-bar interposer 116 surrounds the PHS 108 (in the x-y directions) and may be made from a plastic material with external vias 118 (as opposed to internal vias 106) extending from a first surface 120 adjacent to the metallization layer 102 to a second surface 122 (i.e., in the z-axis) spaced from the metallization layer 102. As better illustrated in FIG. 4, there is no strict requirement to surround the PHS 108. An overmold material 119 (also referred to as a mold compound) may fill the space between the metallization layer 102 to the height (approximately) (z-axis) of the e-bar interposer 116.

The package 100 may be mounted on a PCB 124, such as through a solder ball or other conductive coupling that couples the vias 118 to conductors (not shown) in the PCB 124. This coupling may be referred to as communicatively coupling with the electrical connections forming a path that communicatively couples elements in the dice 110(1)-110(P) to the conductors in the PCB 124 to allow signals to pass therethrough. In exemplary aspects, the signals may contain clock information, data, power, or the like. On the other side of the package 100 (as illustrated, towards the “top” in the z-axis), the PHS 108 may couple to a thermal interface material (TIM) 126. The TIM 126 may couple to a heat sink 128, which may be a metal material, have a fan mounted thereon, or the like. It should be appreciated that the TIM 126 and heat sink 128 are applied during installation in a final product and are not central to the present disclosure. Rather, of greater interest is the ability to route heat through a PHS 108 to a top side and route signal paths through a bottom side (e.g., through the e-bar interposer 116) thereby creating separate signal and heat paths. Thus, the top side (e.g., the PHS 108 and a top side of the metallization layer 102) is configured to couple to a heat sink 128, such as through TIM 126. Likewise, the bottom side is configured to couple to a PCB 124 or other mounting material. As explained above, this notion of “top” and “bottom” are used to help provide explanation of relative positions and not intended to be strictly limited.

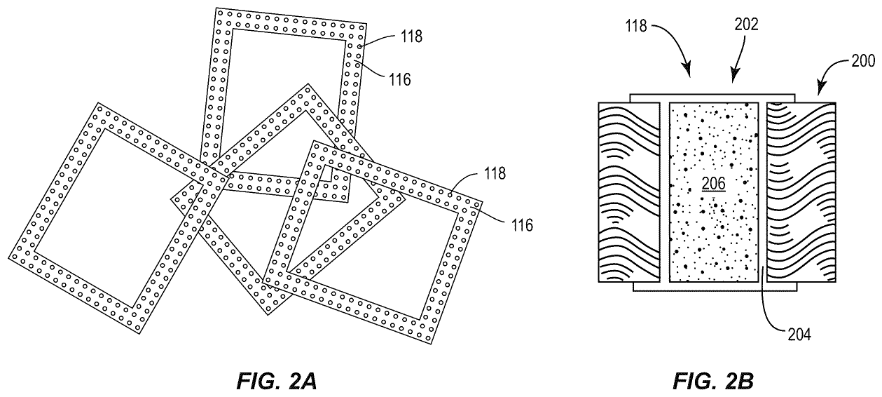

FIGS. 2A and 2B provide additional details about the e-bar interposer 116 and vias 118. The e-bar interposer 116 may be formed from a plastic material 200 and have channels 202 drilled therethrough. While drilling is specifically contemplated, other techniques may be used to form the channels 202 without departing from the present disclosure. The channels 202 are plated with a conductive material 204 (e.g., copper, aluminum, gold, etc.) and may be filled with a plug material 206.

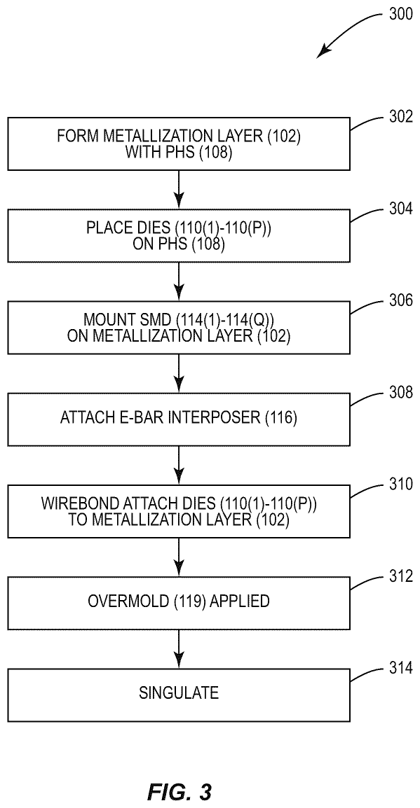

FIG. 3 provides a flowchart of a process 300 for making a package according to exemplary aspects of the present disclosure. The process 300 begins with forming a metallization layer 102 with a PHS 108 therein (block 302). The dies 110(1)-110(P) are placed on the PHS 108 (block 304). SMDs 114(1)-114(Q) are then mounted on the metallization layer 102 (block 306). The e-bar interposer 116 is attached (block 308). Note that blocks 304, 306, and 308 may be switched temporally or done concurrently with the same pick-and-place machinery if desired. The power amplifiers (PAs) (or more generally the dies 110(1)-110(P)) are then wire bond attached to the metallization layer 102 (block 310). Again, this step may be done earlier in the process if desired.

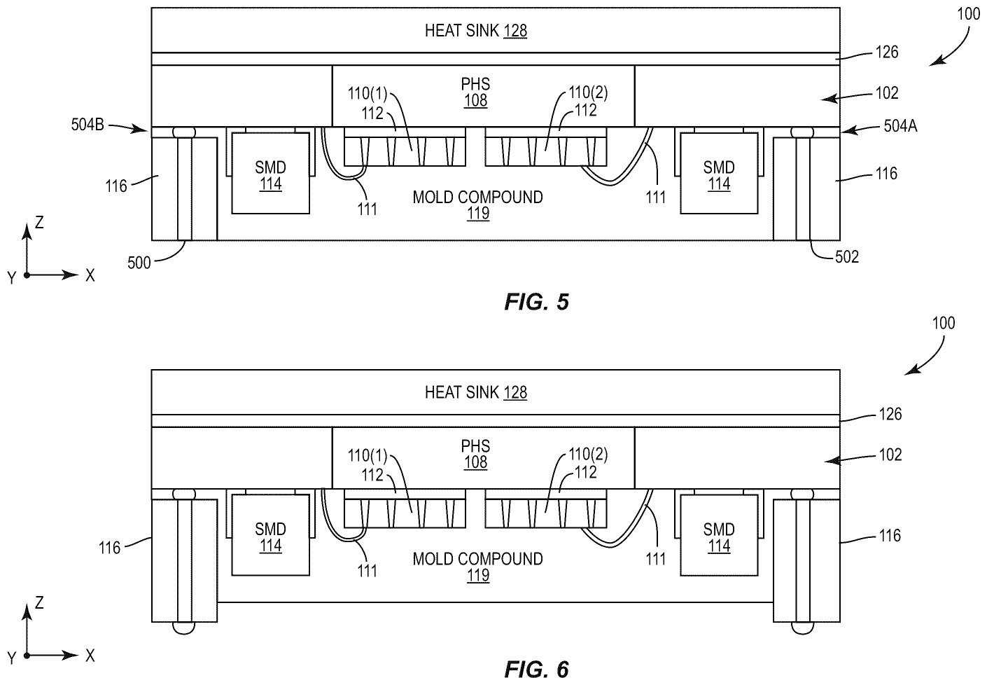

When the basic structures are in place, an overmold material 119 is then applied (block 312). Various ways of doing applying overmold material 119 are set forth with reference to FIGS. 5-9 below. Packages may be singulated to finish the process 300 (block 314).

Instead of an e-bar interposer 116 that surrounds the PHS 108, the interposers may be non-continuous, discrete elements, as is better seen in FIG. 4. Specifically, interposer modules 400 may be used. In an exemplary aspect, interposer modules 400 include two rows of vias 402, where each row has three to six (although more are possible) vias 402. One module 400 may be positioned on each side of the package 100, with one row in a first package and the other row in a second package. During singulation, the rows are split such that a single row from four modules 400 is present in each package. The use of the initial double-row arrangement may promote stability, such as during solder reflow. Note that while FIG. 4 contemplates a module 400 on each side of the package, fewer modules may be used (i.e., on two or three sides only). Likewise, while shown as centered on a side, the modules 400 may be off center if needed or desired. Still further, the present disclosure contemplates that more than one module 400 may be on a given side. Placement of the modules 400 may be rearranged to facilitate routing through metallization layer 102, provide additional vias 402 to provide connections for pins on the dies 110(1)-110(P) and/or pins on the SMD 114, or the like.

FIGS. 5-9 illustrate various ways that the overmold material 119 may be applied for the package. The precise details are not central to the present disclosure, and any of these methods or variations thereon may be used without departing from the present disclosure.

In this regard, FIG. 5 illustrates a first overmold technique. Specifically, a film may be placed on a plane extending between surfaces 500, 502 of the interposer 116. Overmold material 119 may be injected from the sides (e.g., at points 504A, 504B), filling the space over the dice 110(1)-110(P) and the SMDs 114.

FIG. 6 contemplates a glob top approach to the overmold material 119. In this approach, a needle dispenses overmold material 119 in layers over the dice 110(1)-110(P) and SMD 114. This approach may allow the height (z-axis) of the overmold material 119 to be controlled more readily.

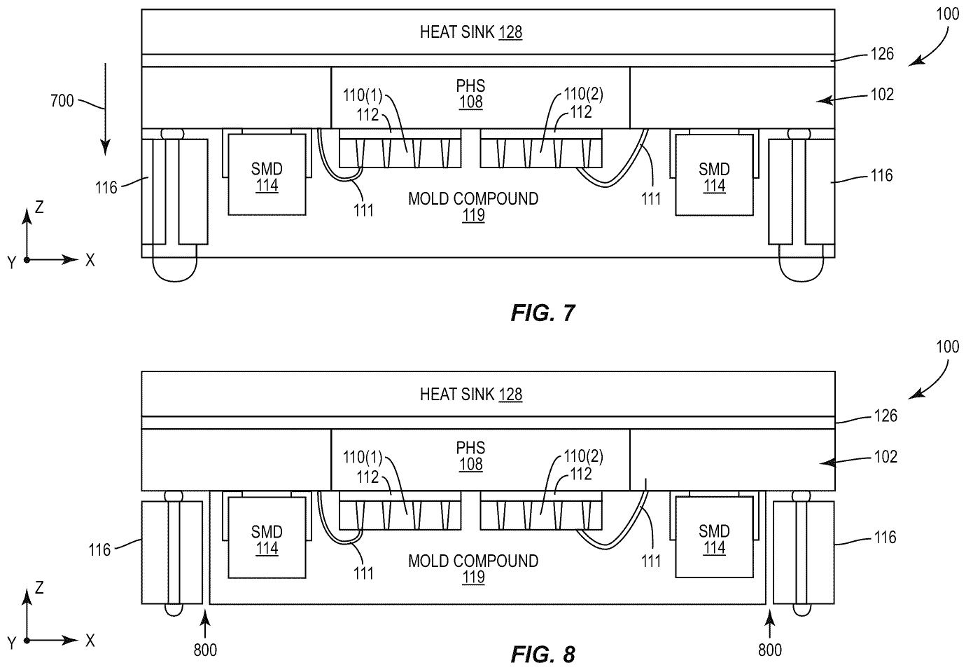

FIG. 7 contemplates a compression mold approach where the package 100 is pressed down (see arrow 700 in z-axis) into an uncured volume of overmold compound, cured, and then ground down to expose the interposer 116 while leaving overmold material 119 over the dice 110(1)-110(P) and SMD 114.

FIG. 8 contemplates adding the overmold material 119 initially in a pattern that leaves room for the interposer 116, which is added subsequently. This approach may leave a channel 800 between the overmold material 119 and the interposer 116.

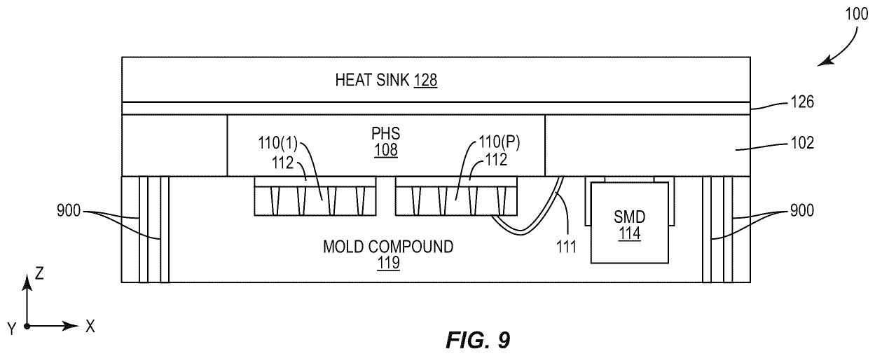

FIG. 9 uses vertical wire bonds 900 that are not specifically in an interposer 116. The overmold material 119 flows around and encloses the wire bonds 900 to hold them in position and allow for interconnection of conductors in the metallization layer 102 to the PCB. Note that, as used herein the term external via also includes these vertical wire bonds 900.

Another approach that may be used in isolation or with one of the techniques of FIGS. 5-9 uses laser ablating to shape the overmold material 119. Specifically, the overmold material 119 is applied through any appropriate technique and then ablated to expose the external vias 118 or otherwise expose sufficient metal to form a communicative coupling. A solder ball may then be attached to the freshly exposed metal of the external vias 118. In an exemplary aspect, each external via 118 may have its own respective solder ball. The solder ball may then be used to attach to a complementary contact pad on the PCB 124.

The systems and methods for top side cooling of a power amplifier module, according to aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

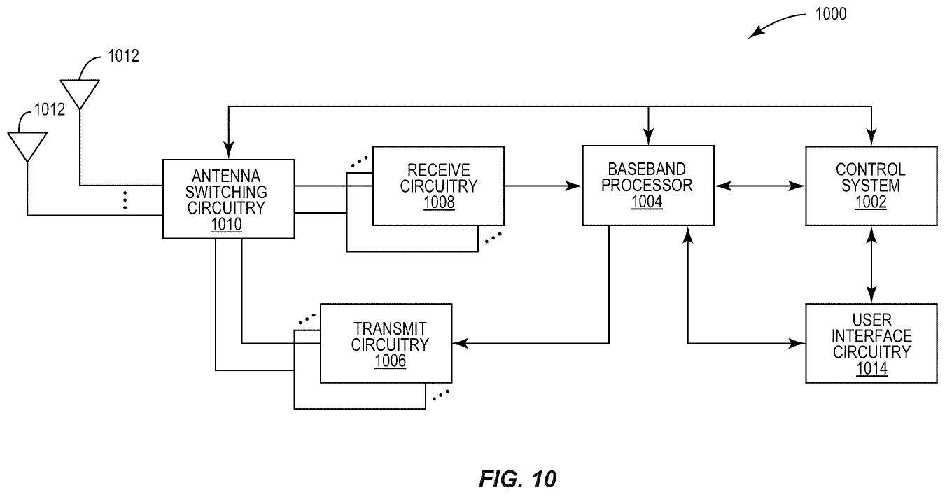

With reference to FIG. 10, the concepts described above may be implemented in various types of user elements 1000, such as those listed in the previous paragraph. The user elements 1000 will generally include a control system 1002, a baseband processor 1004, transmit circuitry 1006, which may include the power amplifier module of FIGS. 1A-6, receive circuitry 1008, antenna switching circuitry 1010, multiple antennas 1012, and user interface circuitry 1014. In a non-limiting example, the control system 1002 can be a field-programmable gate array (FPGA) or an application-specific integrated circuit (ASIC), as an example. In this regard, the control system 1002 can include at least a microprocessor(s), an embedded memory circuit(s), and a communication bus interface(s). The receive circuitry 1008 receives radio frequency signals via the antennas 1012 and through the antenna switching circuitry 1010 from one or more base stations. A low noise amplifier and a filter of the receive circuitry 1008 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1004 processes the digitized received signal to extract the information or data bits conveyed in the received signal. This processing typically comprises demodulation, decoding, and error correction operations. The baseband processor 1004 is generally implemented in one or more digital signal processors (DSPs) and ASICs.

For transmission, the baseband processor 1004 receives digitized data, which may represent voice, data, or control information, from the control system 1002, which it encodes for transmission. The encoded data is output to the transmit circuitry 1006, where a digital-to-analog converter(s) (DAC) converts the digitally encoded data into an analog signal, and a modulator modulates the analog signal onto a carrier signal that is at a desired transmit frequency or frequencies. A power amplifier within a power amplifier module of the present disclosure will amplify the modulated carrier signal to a level appropriate for transmission and deliver the modulated carrier signal to the antennas 1012 through the antenna switching circuitry 1010 to the antennas 1012. The multiple antennas 1012 and the replicated transmit and receive circuitries 1006, 1008 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

We claim:

1. A package comprising:
a metallization layer comprising:
a plated heat sink (PHS) configured to be coupled to an external heat sink through a first surface;
a plurality of interior metal layers electrically isolated from the PHS; and
a plurality of vias coupling different ones of the plurality of interior metal layers;
a die positioned adjacent to the PHS at a second surface opposite the first surface, the die coupled to at least one of the interior metal layers through a wire bond connection; and
an external via configured to couple the metallization layer to an exterior surface opposite the first surface.

2. The package of claim 1, wherein the die comprises a power amplifier die.

3. The package of claim 1, further comprising an interposer and wherein the external via is within the interposer.

4. The package of claim 3, wherein the interposer surrounds the PHS.

5. The package of claim 3, wherein the interposer comprises a plurality of non-continuous discrete portions.

6. The package of claim 5, wherein at least one of the plurality of non-continuous discrete portions comprises a plurality of external vias.

7. The package of claim 1, further comprising a mold compound covering the die and at least a portion of the metallization layer.

8. The package of claim 7, wherein the mold compound encloses the external via.

9. The package of claim 1, wherein the die is coupled to the PHS with a high thermal sintered material.

10. The package of claim 1, further comprising a surface-mounted device coupled to at least one internal metal layer.

11. A method of routing signals to a die in a package comprising:
generating a signal in a die mounted on a plated heat sink (PHS);
passing the signal through a wire bond from the die to an interior metal layer within a metallization layer; and
passing the signal from the interior metal layer to an external via that routes the signal to an exterior surface opposite the PHS.

12. The method of claim 11, further comprising passing heat from the die through the PHS.

13. The method of claim 11, wherein generating the signal in the die comprises generating the signal in a power amplifier.

14. The method of claim 11, wherein passing the signal to the external via comprises passing the signal to an external via in an interposer.

15. The method of claim 11, wherein passing the signal to the external via comprises passing the signal to a vertical wire bond.

16. A device comprising:
a transceiver comprising:
a package comprising:
a metallization layer comprising:
a plated heat sink (PHS) configured to be coupled to an external heat sink through a first surface;
a plurality of interior metal layers electrically isolated from the PHS; and
a plurality of vias coupling different ones of the plurality of interior metal layers;
a die positioned adjacent to the PHS at a second surface opposite the first surface, the die coupled to at least one of the interior metal layers through a wire bond connection; and
an external via configured to couple the metallization layer to an exterior surface opposite the first surface.

17. The device of claim 16, wherein the die comprises a power amplifier.

18. The device of claim 16, further comprising an interposer and wherein the external via is within the interposer.

19. The device of claim 18, wherein the interposer surrounds the PHS.

20. The device of claim 16 wherein the device comprises one of:
a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.
